(19) United States
(12) Patent Application Publication
(10) Pub. No.: US 2024/0224756 A1
(43) Pub. Date: Jul. 4, 2024

(54) DISPLAY DEVICE

(71) Applicant: LG Display Co., Ltd., Seoul (KR)

(72) Inventors: Eun Young PARK, Paju-si (KR); Yong Cheol KIM, Paju-si (KR); Ju Won OH, Paju-si (KR)

(73) Assignee: LG Display Co., Ltd., Seoul (KR)

(21) Appl. No.: 18/528,449

(22) Filed: Dec. 4, 2023

(30) Foreign Application Priority Data
Dec. 30, 2022 (KR) 10-2022-0190404

(51) Int. Cl. H10K 59/80; H10K 59/121; H10K 59/32; H10K 59/60

(52) U.S. Cl. CPC H10K 59/879; H10K 59/121; H10K 59/32; H10K 59/60

(57) ABSTRACT

A display device can include a first sub light-emitting element, a second sub light-emitting element and a third sub light-emitting element. The first sub light-emitting element includes a 1-1 hole transport layer, a 1-2 hole transport layer disposed on the 1-1 hole transport layer, and a first organic light-emitting layer disposed on the 1-2 hole transport layer. The second sub light-emitting element includes a 2-1 hole transport layer, a 2-2 hole transport layer disposed on the 2-1 hole transport layer, and a second organic light-emitting layer disposed on the 2-2 hole transport layer. The third sub light-emitting element includes a 3-1 hole transport layer, a 3-2 hole transport layer disposed on the 3-1 hole transport layer, and a third organic light-emitting layer disposed on the 3-2 hole transport layer.

### CROSS-REFERENCE TO RELATED APPLICATION

This application claims priority to Korean Patent Application No. 10-2022-0190404, filed on Dec. 30, 2022 in the Republic of Korea, the entire disclosure of which is hereby expressly incorporated by reference into the present application.

### BACKGROUND

### Field

An embodiment of the present disclosure relates to a display device including an organic light-emitting element having improved luminance.

### Discussion of Related Art

An electroluminescence display device is classified into an inorganic light-emitting display device and an organic light-emitting display device according to the material of a light-emitting layer.

An active-matrix type organic light-emitting display device includes an organic light-emitting diode (OLED) that emits light by itself, and has advantages of a quick response time, high luminous efficiency, high luminance, and a wide viewing angle. In the organic light-emitting display device, an OLED is formed in each pixel. The organic light-emitting display device not only has a quick response time, excellent luminous efficiency, excellent luminance, and a wide viewing angle, but also represents a black grayscale as perfect black, and thus has an excellent contrast ratio and color gamut.

Multimedia functions of a mobile terminal are being studied and have been improving. For example, a camera is basically built in a smart phone, and the resolution of the camera tends to increase to the level of a conventional digital camera. However, a front camera of the smart phone can limit a screen design, and makes it challenging to design a screen.

In order to reduce the space occupied by the camera, although a screen design including a notch or punch hole has been developed for the some smart phone, since a screen size is still limited due to the camera, it can be challenging to implement a full-screen display.

In order to implement a full-screen display, a method of providing an imaging region where low-resolution pixels are disposed in a screen of a display panel and disposing a camera and/or various sensors at a position facing the imaging region under the display panel has been proposed.

However, since the number of pixels disposed in the imaging region is relatively small, there can be a limitation in that the luminance of a display region and the luminance of the imaging region may not be uniform.

### SUMMARY OF THE DISCLOSURE

According to an embodiment of the present disclosure, a display device in which the luminance of an imaging region is increased is provided.

According to an embodiment of the present disclosure, a display device in which the luminance uniformity of a display region and an imaging region is improved is provided.

Objects of the present disclosure are not limited to the above-mentioned objects, and other objects which are not mentioned will be clearly understood by those skilled in the art from the following disclosure.

A display device according to one feature of the present disclosure includes a first sub light-emitting element including a 1-1 hole transport layer, a 1-2 hole transport layer disposed on the 1-1 hole transport layer, and a first organic light-emitting layer disposed on the 1-2 hole transport layer; a second sub light-emitting element including a 2-1 hole transport layer, a 2-2 hole transport layer disposed on the 2-1 hole transport layer, and a second organic light-emitting layer disposed on the 2-2 hole transport layer; and a third sub light-emitting element including a 3-1 hole transport layer, a 3-2 hole transport layer disposed on the 3-1 hole transport layer, and a third organic light-emitting layer disposed on the 3-2 hole transport layer, wherein a refractive index of the 1-1 hole transport layer is greater than (larger than) a refractive index of the 1-2 hole transport layer, and a refractive index of the 2-1 hole transport layer is less than (smaller than) a refractive index of the 2-2 hole transport layer.

According to an aspect of the present disclosure, the refractive index of the 1-1 hole transport layer can be greater than the refractive index of the 2-1 hole transport layer, and the refractive index of the 1-2 hole transport layer can be less than the refractive index of the 2-2 hole transport layer.

According to an aspect of the present disclosure, a refractive index of the 3-1 hole transport layer can be less than a refractive index of the 3-2 hole transport layer.

According to an aspect of the present disclosure, the first organic light-emitting layer can emit light in a blue wavelength range, the second organic light-emitting layer can emit light in a green wavelength range, and the third organic light-emitting layer can emit light in a red wavelength range.

According to an aspect of the present disclosure, a thickness of the 1-2 hole transport layer can be thicker than (less than) a thickness of the 1-1 hole transport layer.

According to an aspect of the present disclosure, a thickness of the 2-2 hole transport layer can be thicker than a thickness of the 2-1 hole transport layer.

According to an aspect of the present disclosure, the refractive index of the 1-1 hole transport layer can be greater than the refractive index of the 3-1 hole transport layer, and the refractive index of the 1-2 hole transport layer can be less than the refractive index of the 3-2 hole transport layer.

According to an aspect of the present disclosure, the refractive indices of the 1-1 hole transport layer, the 2-2 hole transport layer, and the 3-2 hole transport layer can be the same.

According to an aspect of the present disclosure, the refractive indices of the 1-2 hole transport layer, the 2-1 hole transport layer, and the 3-1 hole transport layer can be the same.

According to an aspect of the present disclosure, the second sub light-emitting element can include a 2-3 hole transport layer disposed between the 2-1 hole transport layer and the 2-2 hole transport layer, the third sub light-emitting element can include a 3-3 hole transport layer disposed between the 3-1 hole transport layer and the 3-2 hole transport layer, a refractive index of the 2-3 hole transport layer can be greater than the refractive index of the 2-1 hole transport layer and less than the refractive index of the 2-2 hole transport layer, and a refractive index of the 3-3 hole transport layer can be greater than the refractive index of the 3-1 hole transport layer and less than the refractive index of the 3-2 hole transport layer.

A display device according to another feature of the present disclosure includes a first display region where a plurality of first pixels are disposed; and a second display region including a pixel region where a plurality of second pixels are disposed, and a plurality of light transmission regions disposed between the plurality of second pixels, wherein the number of the plurality of second pixels is less than the number of the plurality of first pixels, the plurality of first pixels include a first organic light-emitting element, the plurality of second pixels include a second organic light-emitting element, and a refractive index of a hole transport layer of the first organic light-emitting element is different from a refractive index of a hole transport layer of the second organic light-emitting element.

### BRIEF DESCRIPTION OF THE DRAWINGS

The above and other objects, features and advantages of the present disclosure will become more apparent to those of ordinary skill in the art by describing in detail exemplary embodiments thereof with reference to the accompanying drawings, in which:

FIG. 1 is a conceptual diagram of a display device according to one embodiment of the present disclosure;

FIG. 2 is a cross-sectional view schematically illustrating a display panel according to one embodiment of the present disclosure;

FIG. 3 is a view illustrating a pixel arrangement of a first display region according to one embodiment of the present disclosure;

FIG. 4 is a view illustrating pixels and a light transmission region of a second display region according to one embodiment of the present disclosure;

FIG. 5 is a cross-sectional view of the pixels disposed in the first display region and the second display region according to one embodiment of the present disclosure;

FIG. 6 is a view illustrating a first organic light-emitting element disposed in the first display region;

FIG. 7 is a view illustrating a second organic light-emitting element according to a first embodiment of the present disclosure;

FIG. 8A is a view illustrating a change in efficiency according to an increase in refractive index of a red light-emitting element;

FIG. 8B is a view illustrating a change in efficiency according to an increase in refractive index of a green light-emitting element;

FIG. 8C is a view illustrating a change in efficiency according to an increase in refractive index of a blue light-emitting element;

FIG. 9 is a view illustrating a change in efficiency according to an increase in refractive index of the green light-emitting element;

FIG. 10 is a view illustrating a change in efficiency according to an increase in refractive index of the blue light-emitting element;

FIG. 11 is a view illustrating a change in current density of the blue light-emitting element according to a change in voltage;

FIG. 12 is a view illustrating a second organic light-emitting element according to a second embodiment of the present disclosure;

FIG. 13 is a view illustrating a second organic light-emitting element according to a third embodiment of the present disclosure;

FIG. 14 is a view illustrating a second organic light-emitting element according to a fourth embodiment of the present disclosure;

FIG. 15 is a view illustrating a second organic light-emitting element according to a fifth embodiment of the present disclosure;

FIG. 16 is a view illustrating the display device according to one embodiment of the present disclosure;

FIG. 17 is a view illustrating a driving circuit according to one embodiment of the present disclosure;

FIG. 18 is a view illustrating a change in capacitance of the organic light-emitting element according to a change in voltage; and

FIG. 19 is a view illustrating an energy level of the organic light-emitting element.

### DETAILED DESCRIPTION OF THE EMBODIMENTS

Advantages and features of the present disclosure, and a method of achieving them, will become apparent with reference to preferable embodiments which are described in detail in conjunction with the accompanying drawings. However, the present disclosure is not limited to the embodiments to be described below and can be implemented in different forms, the embodiments are only provided to completely disclose the present disclosure and completely convey the scope of the present disclosure to those skilled in the art, and the present disclosure is defined by the disclosed claims.

Since the shapes, sizes, proportions, angles, numbers, and the like disclosed in the drawings for describing the embodiments of the present disclosure are only exemplary, the present disclosure is not limited to the illustrated items. Like reference numbers indicate like components throughout the specification. Further, in describing the present disclosure, when it is determined that a detailed description of a related known technology can unnecessarily obscure the gist of the present disclosure, the detailed description thereof will be omitted.

When ‘including,’ ‘having,’ ‘consisting,’ and the like mentioned in the present specification are used, other parts can be added unless ‘only’ is used. A case in which a component is expressed in a singular form includes a plural form unless otherwise explicitly stated.

In interpreting the components, it is understood that an error range is included even when there is no separate explicit description.

In the case of a description of a positional relationship, for example, when the positional relationship of two parts is described as ‘on,’ ‘above,’ ‘below,’ ‘next to, and the like, one or more other parts can be located between the two parts unless ‘immediately’ or ‘directly’ is used.

In a description of the embodiment of the present disclosure, first, second, and the like are used to describe various components, but these components are not limited by these terms. These terms are only used to distinguish one component from another. Accordingly, a first component mentioned below can also be a second component within the technical spirit of the present disclosure.

Like reference numbers indicate like components throughout the entire specification.

Features of various embodiments of the present disclosure can be partially or entirely coupled or combined with each other, technically various linkages and driving are possible, and the embodiments can be implemented independently of each other or together in a related relationship.

Hereinafter, various embodiments of the present disclosure will be described in detail with reference to the accompanying drawings. All the components of each display device according to all embodiments of the present disclosure are operatively coupled and configured.

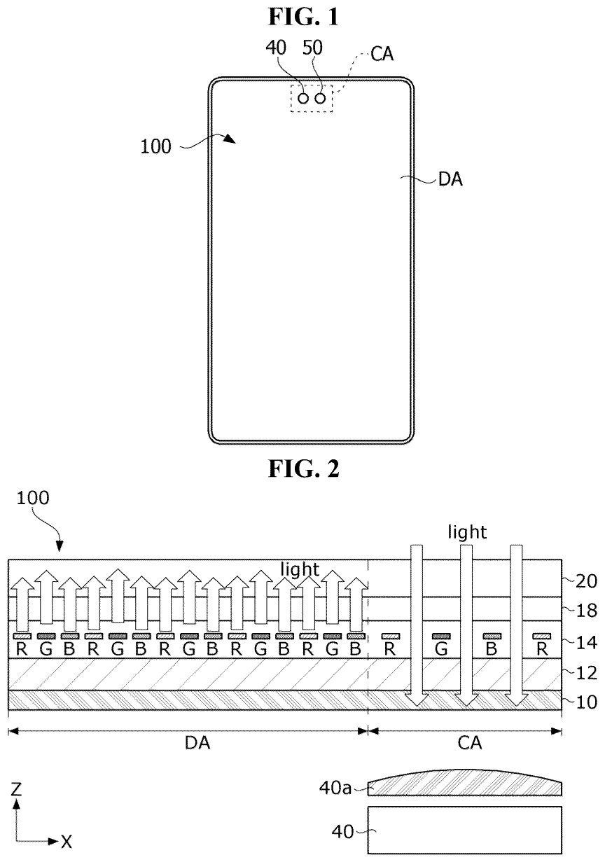

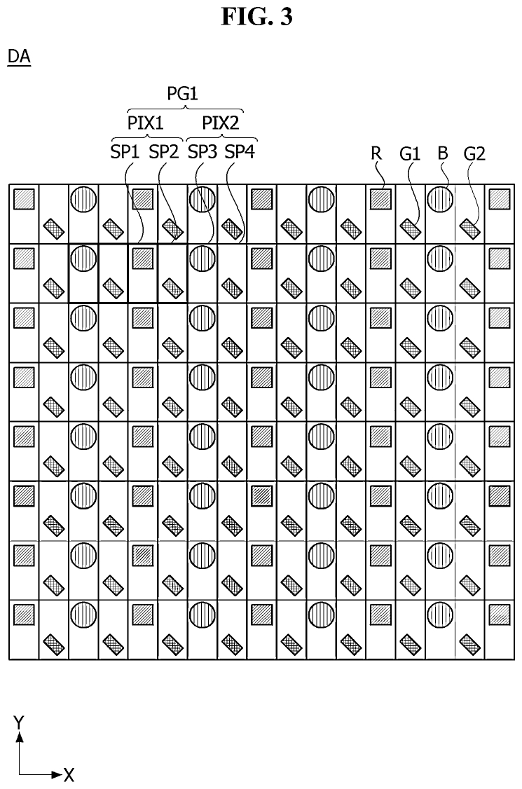

FIG. 1 is a conceptual diagram of a display device according to one embodiment of the present disclosure. FIG. 2 is a cross-sectional view schematically illustrating a display panel according to one embodiment of the present disclosure. FIG. 3 is a view illustrating a pixel arrangement of a first display region according to one embodiment of the present disclosure;

Referring to FIG. 1, in the display device, the entire surface of a display panel 100 can be configured as a display region. Accordingly, a full-screen display can be possible.

The display region can include a first display region DA and a second display region (contact area) CA. Both the first display region DA and the second display region CA output images, but can have different resolutions. For example, the resolution (or density) of a plurality of second pixels disposed in the second display region CA can be lower than the resolution (or density) of a plurality of first pixels disposed in the first display region DA. As the resolution (or density) of the plurality of second pixels disposed in the second display region CA is lowered, a relatively large amount of light can be injected into sensors 40 and 50 disposed in the second display region CA. However, the present disclosure is not necessarily limited thereto, and when the second display region CA has sufficient light transmittance or an appropriate compensation algorithm can be implemented, the resolution of the first display region DA and the resolution of the second display region CA can be the same.

The second display region CA can be a region where the sensors 40 and 50 are disposed. The second display region CA is a region overlapping various sensors, and thus can have a smaller area than the first display region DA which outputs most of the image. The second display region CA can be a sensing region where various sensors collect information. It is illustrated that the second display region CA is disposed at an upper end of the display device, but the present disclosure is not necessarily limited thereto. The location and area of the second display region CA can be variously modified.

The sensors 40 and 50 can each include at least one of an image sensor, a proximity sensor, an illuminance sensor, a gesture sensor, a motion sensor, a fingerprint recognition sensor, a biometric sensor, etc. For example, the first sensor 40 can be an imaging unit which captures images or videos, and the second sensor 50 can be an illuminance sensor or an infrared sensor, but is not necessarily limited thereto.

Referring to FIGS. 2 and 3, the first display region DA and the second display region CA can include a pixel array in which pixels on which pixel data is written are disposed. The number of pixels per inch (hereinafter, referred to as “PPI”) of the second display region CA can be lower than that of the first display region DA to secure the light transmittance of the second display region CA.

The pixel array of the first display region DA can include a pixel region where a plurality of pixels having a high PPI are disposed. The pixel array of the second display region CA can include a pixel region where a plurality of pixels spaced apart by a light transmission region and thus having a relatively low PPI are disposed. In the second display region CA, external light can pass through the display panel 100 through a light transmission region having high light transmittance, and can be received by a sensor under the display panel 100.

Since both the first display region DA and the second display region CA include pixels, an input image can be implemented on the first display region DA and the second display region CA. Accordingly, a full-screen display can be possible.

Each of the pixels of the first display region DA and the second display region CA can include sub-pixels having different colors for implementing a color of the image. The sub-pixels can include red, green, and blue sub-pixels. The pixels can further include white sub-pixels. Each of the sub-pixels can include a pixel circuit and red, green, and blue light-emitting elements (organic light-emitting diodes (OLEDs)).

The second display region CA can include pixels and an imaging unit 40 disposed under the screen of the display panel 100. The imaging unit 40 can include an image sensor. The pixels of the second display region CA can display an input image as pixel data of the input image is written in a display mode.

The imaging unit 40 can capture an external image in an imaging mode and output photo or moving image data. A lens 40a of the imaging unit 40 can face the second display region CA. External light can be incident on the lens 40a of the imaging unit 40 through the second display region CA, and the lens 40a can concentrate the light. The imaging unit 40 can be a camera module, but is not necessarily limited thereto, and can be various image acquisition devices capable of acquiring an image or an optical sensor.

An image quality compensation algorithm for compensating the luminance and color coordinates of pixels in the second display region CA can be applied due to the pixels removed from the second display region CA in order to secure light transmittance.

The display panel 100 can have a width in an X-axis direction, a length in a Y-axis direction, and a thickness in a Z-axis direction. The display panel 100 can include a circuit layer 12 disposed on a substrate 10 and a light-emitting element layer 14 disposed on the circuit layer 12. A polarization plate 18 can be disposed on the light-emitting element layer 14, and a cover glass 20 can be disposed on the polarization plate 18.

The circuit layer 12 can include a pixel circuit connected to lines such as data lines, gate lines, power lines, and the like, a gate driver connected to the gate lines, and the like.

The circuit layer 12 can include circuit elements such as transistors implemented as thin film transistors (TFTs), capacitors, and the like. The lines and the circuit elements of the circuit layer 12 can be implemented as a plurality of insulating layers, two or more metal layers separated from each other with the insulating layer therebetween, and an active layer including a semiconductor material.

The light-emitting element layer 14 can include light-emitting elements driven by the pixel circuit. The light-emitting element can be implemented as an OLED. The OLED can include an organic compound layer formed between an anode and a cathode.

The light-emitting element layer 14 is disposed on pixels selectively transmitting red, green, and blue wavelengths, and can further include a color filter array.

The light-emitting element layer 14 can be covered by a protective film, and the protective film can be covered by an encapsulation layer. Each of the protective film and the encapsulation layer can be a structure in which organic films and inorganic films are alternately stacked. The inorganic film can block the penetration of moisture or oxygen. The organic film can planarize the surface of the inorganic film. When the organic films and the inorganic films are stacked in several layers, since a movement path of the moisture or oxygen is extended compared to a single layer, the penetration of moisture/oxygen which affect the light-emitting element layer 14 can be effectively blocked.

The polarization plate 18 can be disposed on the encapsulation layer. The polarization plate 18 can improve the outdoor visibility of the display device. The polarization plate 18 can reduce light reflected from the surface of the display panel 100 and block light reflected from the metal of the circuit layer 12 to improve the brightness of the pixels. The polarization plate 18 can be implemented as a polarization plate in which a linear polarization plate and a retardation film are bonded together or a circular polarization plate.

Referring to FIG. 3, the first display region DA can include a plurality of first pixels PG1 arranged in a matrix form. Each of the plurality of first pixels PG1 can include R, G1, G2, and B sub-pixels. For example, Each of the plurality of first pixels PG1 can include a first unit pixel PIX1 and a second unit pixel PIX2, the first unit pixel PIX1 can include R and G1 sub-pixels SP1 and SP2, and the second unit pixel PIX2 can include B and G2 sub-pixels SP3 and SP4. However, the present disclosure is not necessarily limited thereto, and the plurality of first pixels PG1 can be real-type pixels including RGB sub-pixels.

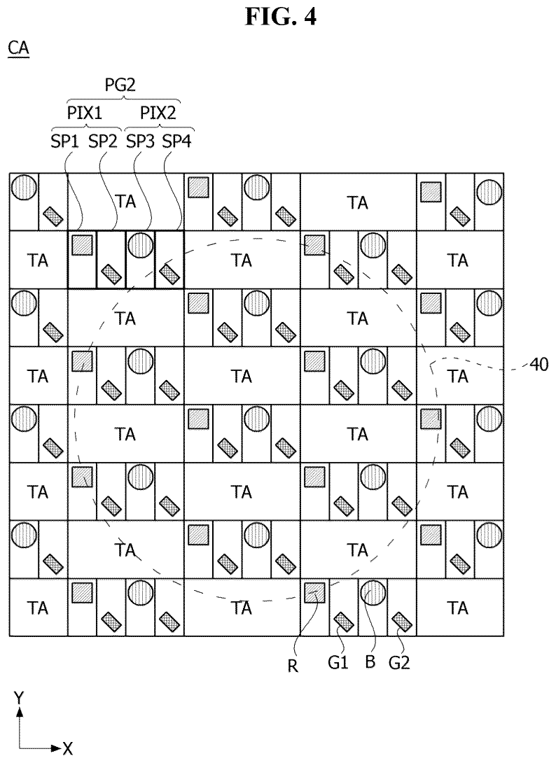

FIG. 4 is a view illustrating an example of the pixels and light transmission region of the second display region according to one embodiment of the present disclosure.

Referring to FIG. 4, the second display region CA can include a plurality of second pixels PG2 and a plurality of light transmission regions TA. The plurality of light transmission regions TA can be disposed between the plurality of second pixels PG2. Specifically, the light transmission regions TA can be disposed alternately with the second pixels PG2 in a first direction and a second direction. External light can be received by the imaging unit 40 through the light transmission regions TA. The resolution of the second display region CA can become smaller than the resolution of the first display region DA as an area of the light transmission region TA increases.

The light transmission regions TA can include transparent media having high light transmittance without metal so that light can be incident with minimal light loss. The light transmission regions TA can be formed of transparent insulating materials without including metal lines or pixels. The light transmittance of the second display region CA can increase as the light transmission region TA is larger.

Each of the plurality of second pixels PG2 can include one or two pixels. For example, in the second pixel PG2, a first unit pixel PIX1 can be composed of R and G1 sub-pixels SP1 and SP2, and a second unit pixel PIX2 can be composed of B and G2 sub-pixels SP3 and SP4. The pixel shape and arrangement of the second pixel PG2 can be the same as or different from the pixel shape and arrangement of the first pixel PG1.

The shape of the light transmission region TA is illustrated as a quadrangular shape, but is not limited thereto. For example, the light transmission region TA can be designed in various shapes such as a circular shape, an oval shape, a polygonal shape, and the like.

All metal electrode materials can be removed from the light transmission region TA. Accordingly, the lines of the pixels can be disposed outside the light transmission region TA. Accordingly, light can be effectively incident through the light transmission region. However, the present disclosure is not necessarily limited thereto, and the metal electrode materials can be present in a partial region of the light transmission region TA.

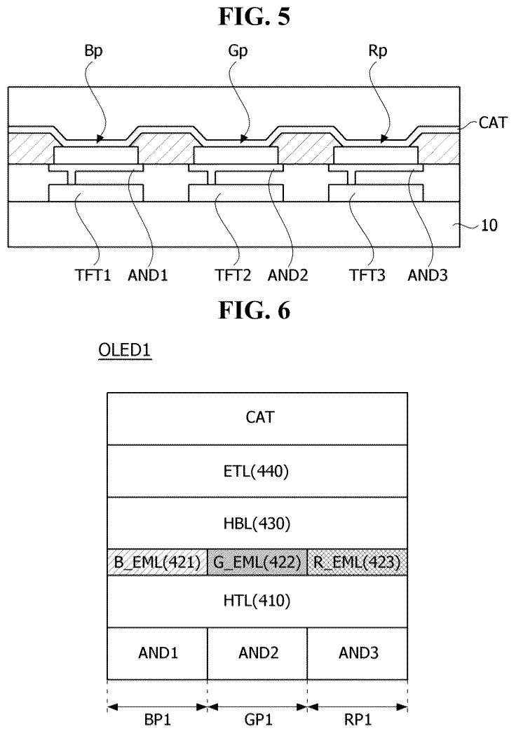

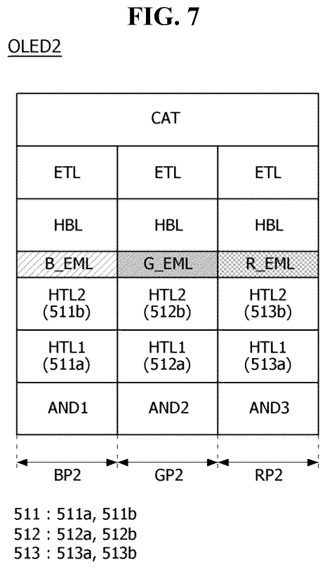

FIG. 5 is a cross-sectional view of an example of the pixels disposed in the first display region and the second display region according to one embodiment of the present disclosure. FIG. 6 is a view illustrating an example of a first organic light-emitting element disposed in a first pixel region. FIG. 7 is a view illustrating an example of a second organic light-emitting element disposed in a second pixel region according to a first embodiment of the present disclosure.

Referring to FIG. 5, each of the first organic light-emitting element disposed in the first display region and the second organic light-emitting element disposed in the second display region can include a first sub light-emitting element BP disposed on a first anode AND1, a second sub light-emitting element GP disposed on a second anode AND2, and a third sub light-emitting element RP disposed on a third anode AND3.

The first sub light-emitting element BP can be a blue light-emitting element, the second sub light-emitting element GP can be a green light-emitting element, and the third sub light-emitting element RP can be a red light-emitting element. However, other color combinations are possible. Further, each of the first organic light-emitting element and the second organic light-emitting element can include a fourth sub light-emitting element (a green or white element) according to a pixel type.

A plurality of driving elements TFT1, TFT2, and TFT3 can be disposed under the first to third anodes AND1, AND2, and AND3, respectively. The plurality of driving elements TFT1, TFT2, and TFT3 can output light by selectively applying power to the first to third anodes AND1, AND2, and AND3.

Referring to FIGS. 6 and 7, a first organic light-emitting diode OLED1 disposed in the first display region can include a hole transport layer HTL, a light-emitting layer (an emission layer, EML), and an electron transport layer ETL which are disposed on the anodes.

A hole injection layer HIL can be disposed between the hole transport layer HTL and the anodes AND1 to AND3, and an electron injection layer EIL can be further disposed between the electron transport layer ETL and a cathode CAT. Further, an electron blocking layer EBL can be disposed on the hole transport layer HTL to block the flow of electrons which can flow to the hole transport layer HTL.

A first sub light-emitting element to a third sub light-emitting element BP1, GP1, and RP1 of the first organic light-emitting element OLED1 and a first sub light-emitting element to a third sub light-emitting element BP2, GP2, and RP2 of a second organic light-emitting element OLED2 can each include the hole transport layer HTL, the light-emitting layer EML, and the electron transport layer ETL. The drawing shows that the first sub light-emitting element to the third sub light-emitting element are connected to each other, but the first sub light-emitting element to the third sub light-emitting element can be spaced apart from each other in the display panel.

The hole transport layer HTL can be disposed on the hole injection layer HIL to facilitate hole transport, and can be formed of any one or more selected from the group consisting of N, N-dinaphthyl-N, N′-diphenylbenzidine (NPD), N, N′-bis-(3-methylphenyl)-N,N′-bis-(phenyl)-benzidine (TPD), s-TAD, and 4,4′,4″-Tris(N-3-methylphenyl-N-phenyl-amino)-triphenylamine (MTDATA), but is not limited thereto.

A red light-emitting layer R-EML can include a light-emitting material which emits red light and can be disposed on the hole transport layer HTL.

The red light-emitting layer R-EML can include a host material including carbazole biphenyl (CBP) or 1,3-bis (carbazol-9-yl) (mCP), can be formed of a phosphorescent material including a dopant including any one or more selected from the group consisting of bis(1-phenylisoquinoline acetylacetonate iridium (PIQIr(acac)), bis(1-phenylquinoline) acetylacetonate iridium (PQIr(acac)), tris(1-phenylquinoline) iridium (PQIr), and octaethylporphyrin platinum (PtOEP), or alternatively, can be formed of a fluorescent material including PBD:Eu(DBM)3(Phen) or Perylene, but is not limited thereto.

A green light-emitting layer G-EML can include a host material including CBP or mCP, can be formed of a phosphorescent material including a dopant material such as an Ir complex including Ir(ppy)3(fac tris(2-phenylpyridine)iridium), or alternatively, can be formed of a fluorescent material including Alq3(tris(8-hydroxyquinolinato)aluminum), but is not limited thereto.

A blue light-emitting layer B-EML can include a host material including CBP or mCP, and can be formed of a phosphorescent material including a dopant material including (4,6-F2ppy)2Irpic. Further, the blue light-emitting layer B-EML can be formed of a fluorescent material including any one selected from the group consisting of spiro-DPVBi, spiro-6P, distylbenzene (DSB), distryl arylene (DSA), a PFO-based polymer, and a PPV-based polymer, but is not limited thereto.

The electron transport layer ETL can be disposed on a hole blocking layer HBL to facilitate electron transport, and can be formed of any one or more selected from the group consisting of Alq3(tris(8-hydroxy-quinolinato)aluminum), 2-(4-biphenyl)-5-(4-tert-butylphenyl)-1,3,4-oxadiazole (PBD), 3-(4-biphenyl)4-phenyl-5-tert-butylphenyl-1,2,4-triazole (TAZ), spiro-PBD, BAlq(bis(2-methyl-80quiolinolate)-4-(phenylphenolato)aluminum), Liq(8-hydroxyquinolinolato-lithium), 5,5′-bis(dimethylboryl)-2,2′: 5,′2″-terthiophene (BMB-3T), perfluoro-2-naphthyl-substituted (PF-6P), 2,2,′2″-(1,3,5-benzinetriyl)-tris(1-phenyl-1-H-benzimidazole) (TPBi), and cyclooctatetraene (COT), but is not limited thereto.

The hole injection layer HIL can be disposed between the anodes AND1 to AND3 and the hole transport layer HTL to facilitate hole injection, and can be formed of any one or more selected from the group consisting of 1,4,5,8,9,11-hexaazatriphenylene-hexanitrile (HATCN), copper phthalocyanine (CuPc), poly(3,4)-ethylenedioxythiophene (PEDOT), polyaniline (PANI), and N,N-dinaphthyl-N,N′-diphenylbenzidine (NPD), but is not limited thereto.

Since the number of pixels in the second display region CA is smaller than the number of pixels in the first display region DA, when the first organic light-emitting element OLED1 and the second organic light-emitting element OLED2 emit light of the same luminance, the luminance of light emitted from the second display region CA can be weaker than the luminance of light emitted from the first display region DA. Accordingly, light uniformity needs to be improved by increasing the output intensity of the second organic light-emitting element OLED2.

In the first organic light-emitting element OLED1 and the second organic light-emitting element OLED2, the light-emitting layers, the electron blocking layers, the hole blocking layers, and the electron transport layers can have the same structure, but the hole transport layers HTL can have different structures.

The first sub-light-emitting element to the third sub-light-emitting element BP1, GP1, and RP1 of the first organic light-emitting element OLED1 can have the hole transport layers HTL having the same refractive index. The refractive index of the hole transport layers HTL can be approximately 1.7 to 1.9. Since the hole transport layer HTL of the first organic light-emitting element OLED1 is a single layer, the refractive indices can be the same in a thickness direction.

A first sub light-emitting element BP2 of the second organic light-emitting element OLED2 can include a 1-1 hole transport layer 511a, a 1-2 hole transport layer 511b disposed on the 1-1 hole transport layer 511a, and a first organic light-emitting layer B_EML disposed on the 1-2 hole transport layer 511b. For example, a first hole transport layer 511 of the first sub light-emitting element BP2 can have a structure in which the 1-1 hole transport layer 511a, which is a lower layer, and the 1-2 hole transport layer 511b, which is an upper layer, are stacked. Here, the terms like “1-1”, “1-2”, “1-3” . . . , “2-1”, “2-2”, . . . , “3-1”, “3-2”, “3-3”, . . . are used to easily reference different layers belonging to different groups/elements, and may not carry other meanings.

A second sub light-emitting element GP2 can include a 2-1 hole transport layer 512a, a 2-2 hole transport layer 512b disposed on the 2-1 hole transport layer 512a, and a second organic light-emitting layer G_EML disposed on the 2-2 hole transport layer 512b. For example, a second hole transport layer 512 of the second sub light-emitting element GP2 can have a structure in which the 2-1 hole transport layer 512a, which is a lower layer, and the 2-2 hole transport layer 512b, which is an upper layer, are stacked.

A third sub light-emitting element RP2 can include a 3-1 hole transport layer 513a, a 3-2 hole transport layer 513b disposed on the 3-1 hole transport layer 513a, and a third organic light-emitting layer R_EML disposed on the 3-2 hole transport layer 513b. For example, a third hole transport layer 513 of the third sub light-emitting element RP2 can have a structure in which the 3-1 hole transport layer 513a, which is a lower layer, and the 3-2 hole transport layer 513b, which is an upper layer, are stacked.

For example, the first organic light-emitting layer B_EML can be a blue light-emitting layer, the second organic light-emitting layer G_EML can be a green light-emitting layer, and the third organic light-emitting layer R_EML can be a red light-emitting layer.

According to the embodiment, the refractive index of the 1-1 hole transport layer 511a can be greater than the refractive index of the 1-2 hole transport layer 511b, and the refractive index of the 2-1 hole transport layer 512a can be smaller than the refractive index of the 2-2 hole transport layer 512b.

Further, the refractive index of the 1-1 hole transport layer 511a can be greater than refractive indices of the 2-1 hole transport layer 512a and the 3-1 hole transport layer 513a, and the refractive index of the 1-2 hole transport layer 511b can be smaller than refractive indices of the 2-2 hole transport layer 512b and the 3-1 hole transport layer 513a.

For example, in the first hole transport layer 511 of the first sub light-emitting element BP2, the lower layer can be a high refractive index layer and the upper layer can be a low refractive index layer. On the other hand, in each of the second hole transport layer 512 of the second sub light-emitting element GP2 and the third hole transport layer 513 of the third sub light-emitting element RP2, the lower layer can be a low refractive index layer and the upper layer can be a high refractive index layer.

Accordingly, each of the hole transport layers of the first sub light-emitting element to the third sub light-emitting element BP2, GP2, and RP2 of the second organic light-emitting element OLED2 can have a section in which the refractive index changes in the thickness direction. The section in which the refractive index changes can be a boundary between the low refractive index layer and the high refractive index layer. On the other hand, the hole transport layer of the first organic light-emitting element OLED1 can have a constant refractive index in the thickness direction.

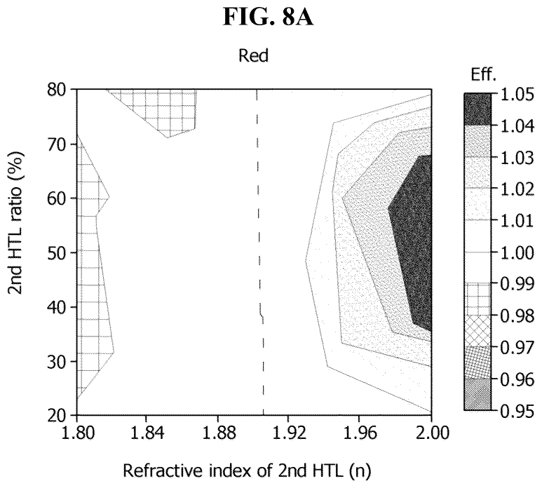

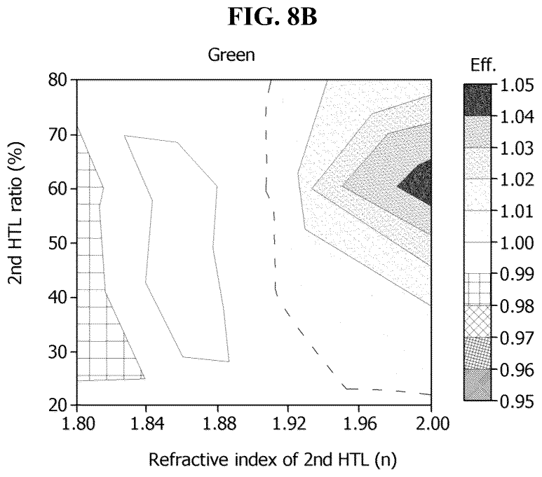

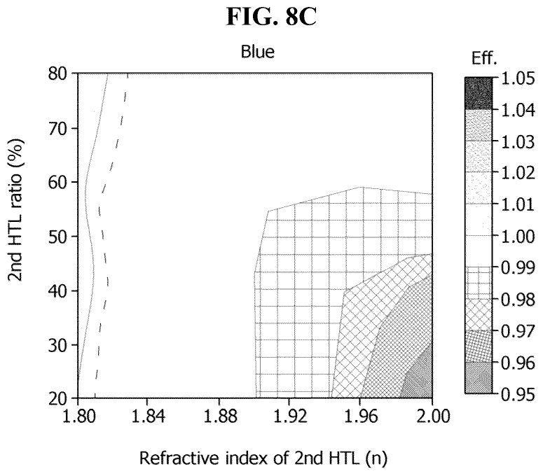

Referring to an example of FIG. 8A, in the case of the red light-emitting element, when the refractive index is 1.89 or more (X-axis increase), it can be seen that the area with high luminous efficiency (e.g., the area where the efficiency Eff. is 1.02 or more) increases, and thus luminous efficiency increases. However, even when a ratio of the second hole transport layer increases (Y-axis increase), it can be seen that there is no significant change in the area with high luminous efficiency, and thus the ratio of the second hole transport layer does not significantly affect luminous efficiency.

Referring to an example of FIG. 8B, in the case of the green light-emitting element, it can be seen that the area with high luminous efficiency increases as the refractive index increases and the ratio of the second hole transport layer increases. Accordingly, it can be seen that the luminous efficiency of the green light-emitting element increases as the refractive index increases and the ratio of the second hole transport layer increases. For example, it can be seen that a long-wavelength cavity increases as the refractive index of the hole transport layer increases.

Referring to an example of FIG. 8C, in the case of the blue light-emitting element, it can be seen that the area with low luminous efficiency (e.g., the area where the efficiency Eff. is 0.98 or less) increases as the refractive index increases, and thus luminous efficiency decreases. On the other hand, it can be seen that the luminous efficiency increases as the refractive index decreases. For example, it can be seen that a short-wavelength cavity increases as the refractive index of the hole transport layer decreases.

In FIGS. 8A to 8C, the X axis is the refractive index of the second hole transport layer (2nd HTL), and the Y axis is a ratio of the second hole transport layer (2nd HTL) to the entire hole transport layer.

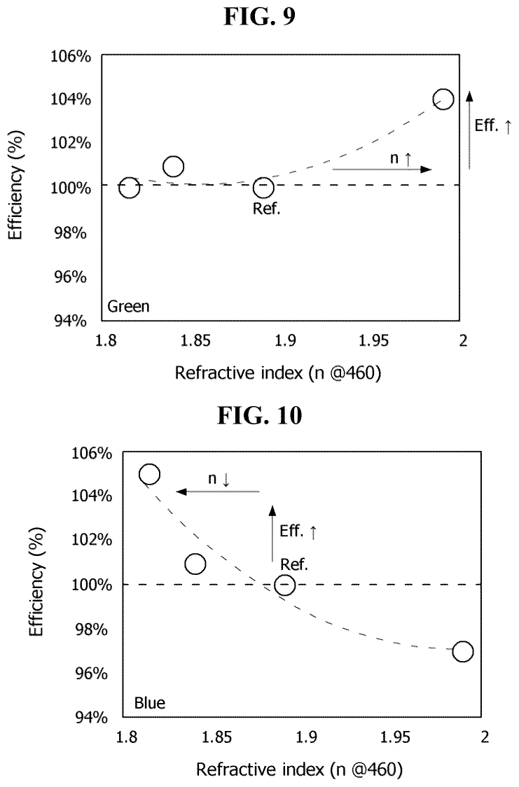

Referring to an example of FIG. 9, in the case of the green light-emitting element, it can be seen that the luminous efficiency gradually increases as the refractive index increases. On the other hand, referring to an example of FIG. 10, in the case of the blue light-emitting element, it can be seen that the luminous efficiency increases as the refractive index decreases.

According to the embodiment, it can be seen that, in the case of the first sub light-emitting element BP2 having a short wavelength, the luminous efficiency increases as the refractive index of the hole transport layer decreases, and in the second sub light-emitting element GP2 having a long wavelength, luminous efficiency can increase by increasing the refractive index of the hole transport layer. Further, it was found that a difference in luminous efficiency according to the change in refractive index of the third sub light-emitting element RP2 is not large. In FIGS. 9 and 10, the X axis is the refractive index of the hole transport layer, and the Y axis is the luminous efficiency.

Referring to FIG. 7 again, the refractive index of the 1-1 hole transport layer 511a can be 1.90 to 2.05, and the refractive index of the 1-2 hole transport layer 511b can be 1.79 to 1.89. Further, the refractive indices of the 2-1 hole transport layer 512a and the 3-1 hole transport layer 513a can be 1.79 to 1.89, and the refractive indices of the 2-2 hole transport layer 512b and the 3-2 hole transport layer 513b can be 1.90 to 2.05. For example, the refractive index range of the low refractive index layer can be 1.79 to 1.89, and the refractive index range of the high refractive index layer can be 1.90 to 2.05.

The refractive indices of the hole transport layers can be adjusted by various methods. For example, the refractive indices can be adjusted by mixing various organic materials and/or inorganic materials (for example, LiF) capable of adjusting the refractive indices. Further, the refractive indices can be adjusted by mixing materials having different dielectric constants.

According to the embodiment, the refractive indices of the 1-1 hole transport layer 511a, the 2-2 hole transport layer 512b, and the 3-2 hole transport layer 513b can be the same. Further, the refractive indices of the 1-2 hole transport layer 511b, the 2-1 hole transport layer 512a, and the 3-1 hole transport layer 513a can be the same. However, the present disclosure is not limited thereto, and the refractive indices of the 1-1 hole transport layer 511a, the 2-2 hole transport layer 512b, and the 3-2 hole transport layer 513b can differ. Further, the refractive indices of the 1-2 hole transport layer 511b, the 2-1 hole transport layer 512a, and the 3-1 hole transport layer 513a can differ.

The thickness of the 1-1 hole transport layer 511a can be thicker than the thickness of the 1-2 hole transport layer 511b, and the thickness of 2-2 hole transport layer 512b can be thicker than the thickness of the 2-1 hole transport layer 512a.

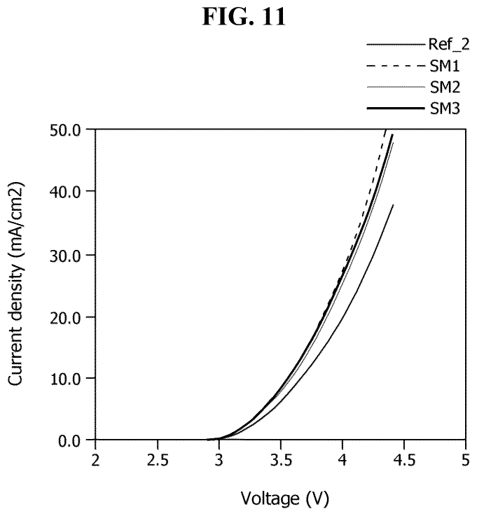

Referring to an example of FIG. 11, an operating voltage of the blue light-emitting element was measured after manufacturing lower hole transport layers with the same material and manufacturing upper hole transport layers with materials having different hole mobility. The upper hole transport layers were manufactured with fast hole mobility materials the hole mobility of which descends in the order of a first experimental example SM1, a second experimental example SM2, and a third experimental example SM3. According to the results of an experiment, it can be seen that the threshold voltage and operating voltage become the lowest in the first experimental example SM1 in which the hole mobility of the upper hole transport layers is the fastest. Accordingly, it can be seen that the operating voltage of the light-emitting element becomes lower as a material having high hole mobility in the hole transport layer is used. A comparative example Ref_2 is a result of an experiment with only the lower hole transport layers of experimental examples.

Table 1 below is a table showing the results of measuring the light output of a blue light-emitting element to which a single hole transport layer is applied (Comparative Example 1) and the light output of a blue light-emitting element in which a high refractive index layer and a low refractive index layer are stacked. A hole transport material having a refractive index of 1.89 and a hole mobility of 2.3×10⁻⁴ cm²/Vs was used for the single hole transport layer used in Comparative Example 1, and in Experimental Examples, a material the same as the hole transport layer of Comparative Example 1 was used for the 1-1 hole transport layer 511a, and a hole transport material having a refractive index of 1.85 and a hole mobility of 2.3×10⁻⁴ cm² Vs was used for the 1-2 hole transport layer 511b. That is, a material having a smaller refractive index than the refractive index of the 1-1 hole transport layer 511a was used for the 1-2 hole transport layer 511b.

TABLE 1

| | Operating | | | Luminous | |
|---|---|---|---|---|---|
| | voltage | CIE x | CIE y | efficiency | |
| Comparative | 3.43 | 0.140 | 0.046 | 8.0 | (100%) |
| Example 1 | | | | | |
| Experimental | 3.93 | 0.140 | 0.046 | 8.1 | (101%) |
| Example 1-1 | | | | | |
| (HTL1:HTL2 = 2:1) | | | | | |
| Experimental | 4.16 | 0.140 | 0.046 | 8.2 | (103%) |
| Example 1-2 | | | | | |
| (HTL1:HTL2 = 1:1) | | | | | |
| Experimental | 4.29 | 0.141 | 0.044 | 8.5 | (106%) |
| Example 1-3 | | | | | |
| (HTL1:HTL2 = 1:2) | | | | | |
| Experimental | 4.32 | 0.141 | 0.043 | 8.6 | (107.5%) |
| Example 1-4 | | | | | |
| (HTL1:HTL2 = 1:4) | | | | | |
| Experimental | 4.30 | 0.141 | 0.043 | 8.55 | (107%) |
| Example 1-5 | | | | | |
| (HTL1:HTL2 = 1:5) | | | | | |
| Experimental | 4.16 | 0.140 | 0.046 | 7.52 | (94%) |
| Example 1-6 | | | | | |
| (HTL2:HTL 1 = 1:1) | | | | | |

Referring to Table 1 above, when hole transport layers having different refractive indices were stacked as in Experimental Example 1-2, the luminous efficiency was improved compared to Comparative Example 1 using a single layer as the hole transport layer. Accordingly, it can be seen that the blue light-emitting element has more excellent luminous efficiency in the case of stacking and using hole transport layers having different refractive indices than in the case of using a single hole transport layer. The luminous efficiency can refer to the intensity of the blue light emitted relative to the injected current.

In the case of Experimental Example 1-1, although the experiment was performed by increasing the thickness of the 1-1 hole transport layer 511a which is a relatively high refractive index layer, the luminous efficiency decreased compared to Experimental Example 1-2 in which a thickness ratio is 1:1.

In the case of Experimental Example 1-3 and Experimental Example 1-4, according to a result of the experiment performed by increasing the thickness of the 1-2 hole transport layer 511b which is a low refractive index layer, the luminous efficiency increased to 106% and 107.5%. However, in the case of Experimental Example 1-5, although the thickness of the 1-2 hole transport layer 511b which is a low refractive index layer was further increased, a luminous efficiency similar to that in Experimental Example 1-4 was measured. Accordingly, it can be seen that a blue light-emitting element can have excellent luminous efficiency when a thickness ratio of the 1-1 hole transport layer 511a and the 1-2 hole transport layer 511b is controlled to 1:1 to 1:4.

Further, in Experimental Example 1-6, the experiment was performed by disposing the 1-1 hole transport layer 511a on the 1-2 hole transport layer 511b. For example, the luminous efficiency experiment was performed by stacking a high refractive hole transport layer on a low refractive hole transport layer. As a result, the luminous efficiency decreased to 94%. Accordingly, it can be seen that the luminous efficiency of a blue light-emitting element is improved when a low refractive hole transport layer is disposed on a high refractive hole transport layer.

In Experimental Examples 1-1 to 1-6, it was found that there was no significant difference between the X coordinate and the Y coordinate on the CIE coordinate system of a blue wavelength.

Table 2 below is a table showing the results of measuring the light output of a green light-emitting element to which a single hole transport layer is applied and the light output of a green light-emitting element in which a low refractive index layer and a high refractive index layer are stacked. A hole transport material having a refractive index of 1.89 and a hole mobility of 2.3×10⁻⁴ cm²/Vs was used for the single hole transport layer used in Comparative Example 2, a material the same as the hole transport layer of Comparative Example 2 was used for the 2-1 hole transport layer 512a, and a hole transport material having a refractive index of 1.99 and a hole mobility of 5.2×10⁻⁴ cm²/Vs was used for the 2-2 hole transport layer 512b. That is, a material having a greater refractive index than the refractive index of the 2-1 hole transport layer 512a was used for the 2-2 hole transport layer 512b.

TABLE 2

| | Operating | | | Luminous | |
|---|---|---|---|---|---|
| | voltage | CIE x | CIE y | efficiency | |
| Comparative | 3.43 | 0.262 | 0.698 | 158.1 | (100%) |
| Example 2 | | | | | |
| Experimental | 3.65 | 0.243 | 0.710 | 159.2 | (100.7%) |
| Example 2-1 | | | | | |
| (HTL1:HTL2 = 3:1) | | | | | |
| Experimental | 3.87 | 0.241 | 0.241 | 160.1 | (101.2%) |
| Example 2-2 | | | | | |
| (HTL1:HTL2 = 1:1) | | | | | |
| Experimental | 3.95 | 0.241 | 0.709 | 160.2 | (101.3%) |
| Example 2-3 | | | | | |
| (HTL1:HTL2 = 1:2) | | | | | |
| Experimental | 4.00 | 0.244 | 0.709 | 163.4 | (103.4%) |
| Example 2-4 | | | | | |
| (HTL 1:HTL2 = 1:4) | | | | | |
| Experimental | 4.30 | 0.243 | 0.709 | 163.3 | (103.4%) |
| Example 2-5 | | | | | |
| (HTL1:HTL2 = 1:5) | | | | | |
| Experimental | 3.87 | 0.242 | 0.241 | 153.3 | (97%) |
| Example 2-6 | | | | | |
| HTL2:HTL1 = 1:1) | | | | | |

Referring to Table 2 above, when hole transport layers having different refractive indices were stacked as in Experimental Example 2-2, the luminous efficiency was improved compared to Comparative Example 2 using a single layer as the hole transport layer. Accordingly, it can be seen that the green light-emitting element has more excellent luminous efficiency in the case of stacking and using hole transport layers having different refractive indices than in the case of using a single hole transport layer.

In the case of Experimental Example 2-1, although the experiment was performed by increasing the thickness of the 2-1 hole transport layer 512a which is a relatively low refractive index layer, the luminous efficiency decreased compared to Experimental Example 2-2 in which a thickness ratio is 1:1.

In the case of Experimental Example 2-3 and Experimental Example 2-4, according to the result of an experiment performed by increasing the thickness of the 2-2 hole transport layer 512b which is a high refractive index layer, the luminous efficiency increased to 101.3% and 103.4%. However, in the case of Experimental Example 2-5, although the thickness of the 2-2 hole transport layer 512b which is a high refractive index layer was further increased, a luminous efficiency similar to that in Experimental Example 2-4 was measured. Accordingly, it can be seen that a green light-emitting element can have excellent luminous efficiency when a thickness ratio of the 2-1 hole transport layer 512a and the 2-2 hole transport layer 512b is controlled to 1:1 to 1:4.

Further, in Experimental Example 2-6, the experiment was performed by disposing the 2-1 hole transport layer 512a on the 2-2 hole transport layer 512b. For example, the luminous efficiency experiment was performed by stacking a low refractive hole transport layer on a high refractive hole transport layer. Accordingly, the luminous efficiency decreased to 97%. As a result, it can be seen that the luminous efficiency of a green light-emitting element is improved when a high refractive hole transport layer is disposed on a low refractive hole transport layer.

Table 3 below is a table showing the results of measuring the light output of a red light-emitting element to which a single hole transport layer is applied (Comparative Example 3) and the light output of a red light-emitting element in which a low refractive index layer and a high refractive index layer are stacked. A hole transport material having a refractive index of 1.89 and a hole mobility of 2.3×10⁻⁴ cm²/Vs was used for the single hole transport layer used in Comparative Example 3, a material the same as the hole transport layer of Comparative Example 3 was used for the 3-1 hole transport layer 513a, and a hole transport material having a refractive index of 1.99 and a hole mobility of 5.2×10⁻⁴ cm²/Vs was used for the 3-2 hole transport layer 513b. That is, a material having a greater refractive index than the refractive index of the 3-1 hole transport layer 513a was used for the 3-2 hole transport layer 513b.

TABLE 3

| | Operating | | | Luminous | |
|---|---|---|---|---|---|
| | voltage | CIE x | CIE y | efficiency | |
| Comparative | 3.27 | 0.679 | 0.318 | 55.6 | (100%) |
| Example 3 | | | | | |
| Experimental | 3.90 | 0.678 | 0.318 | 57.5 | (103.3%) |
| Example 3-1 | | | | | |
| (HTL1:HTL2 = 3:1) | | | | | |
| Experimental | 3.71 | 0.679 | 0.318 | 57.2 | (102.9%) |
| Example 3-2 | | | | | |
| (HTL1:HTL2 = 1:1) | | | | | |
| Experimental | 3.85 | 0.680 | 0.318 | 56.5 | (101.6%) |
| Example 3-3 | | | | | |
| (HTL1:HTL2 = 1:2) | | | | | |
| Experimental | 3.48 | 0.678 | 0.320 | 56.9 | (102.2%) |
| Example 3-4 | | | | | |
| (HTL1:HTL2 = 1:4) | | | | | |
| Experimental | 3.71 | 0.679 | 0.318 | 53.3 | (96%) |
| Example 3-5 | | | | | |
| (HTL2:HTL1 = 1:1) | | | | | |

Referring to Table 3 above, when hole transport layers having different refractive indices were stacked as in Experimental Example 3-2, the luminous efficiency was improved compared to Comparative Example 3 using a single layer as the hole transport layer. Accordingly, it can be seen that the red light-emitting element has more excellent luminous efficiency in the case of stacking and using hole transport layers having different refractive indices than in the case of using a single hole transport layer.

In the case of Experimental Example 3-1, although the experiment was performed by increasing the thickness of the 3-1 hole transport layer 513a which is a relatively low refractive index layer, the luminous efficiency was similar to that in Experimental Example 3-2 in which a thickness ratio is 1:1.

In the case of Experimental Example 3-3 and Experimental Example 3-4, according to the result of an experiment performed by increasing the thickness of the 3-2 hole transport layer 513b which is a high refractive index layer, the luminous efficiency increased to 101.6% and 102.2%. In the case of the red light-emitting element, it was found that the luminous efficiency was improved by stacking two layers having different refractive indices, and it was found that a difference in luminous efficiency according to a change in thickness is not large.

Further, in Experimental Example 3-5, the experiment was performed by disposing the 3-1 hole transport layer 513a on the 3-2 hole transport layer 513b. For example, the luminous efficiency experiment was performed by stacking a low refractive hole transport layer on a high refractive hole transport layer. As a result, the luminous efficiency decreased to 96%. Accordingly, it can be seen that the luminous efficiency of a red light-emitting element is improved when a high refractive hole transport layer is stacked on a low refractive hole transport layer.

Table 4 below is a table showing the results of measuring the light output of a blue light-emitting element to which a single hole transport layer is applied (Comparative Example 4) and the light output of a blue light-emitting element in which a high refractive index layer and a low refractive index layer are stacked. A hole transport material having a refractive index of 1.89 and a hole mobility of 2.3×10⁴ cm²/Vs was used for the single hole transport layer used in Comparative Example 4, and a material having a smaller refractive index than the refractive index of the 1-1 hole transport layer 511a was used for the 1-2 hole transport layer 511b.

TABLE 4

| | | Refractive | | | |
|---|---|---|---|---|---|
| | Operating | index | | | Luminous |
| | voltage | difference | μ1 | μ2 | efficiency |
| Comparative | 3.57 | — | 2.3E−4 | — | 11.0 |
| Example 4 | | | | | (100%) |
| Experimental | 3.53 | 0.04 | 2.3E−4 | 1.1E−2 | 11.5 |
| Example 4-1 | (−0.04) | | | | (105%) |
| (HTL1:HTL2 = | | | | | |
| 8:2) | | | | | |
| Experimental | 3.50 | | | | 11.8 |
| Example 4-2 | (−0.07) | | | | (107%) |
| (HTL1:HTL2 = | | | | | |
| 6:4) | | | | | |
| Experimental | 3.84 | 0.10 | 2.3E−4 | 6.8E−5 | 11.4 |
| Example 5-1 | (+0.27) | | | | (103%) |
| (HTL1:HTL2 = | | | | | |
| 8:2) | | | | | |
| Experimental | 4.10 | | | | 11.3 |
| Example 5-2 | (+0.53) | | | | (103%) |
| (HTL1:HTL2 = | | | | | |
| 6:4) | | | | | |
| Experimental | 3.54 | 0.14 | 5.2E−4 | 1.1E−2 | 11.12 |
| Example 6-1 | (−0.03) | | | | (101%) |
| (HTL1:HTL2 = | | | | | |
| 8:2 | | | | | |
| Experimental | 3.45 | | | | 11.5 |
| Example 6-2 | (−0.12) | | | | (105%) |
| (HTL1:HTL2- | | | | | |
| 6:4) | | | | | |

Referring to Table 4 above, in all Experimental Examples, it can be seen that luminous efficiency is improved by stacking hole transport layers having different refractive indices, compared to Comparative Example 4 using a single layer.

In Experimental Example 4-1 and Experimental Example 4-2, a material having a refractive index of 1.89 and a hole mobility (1) of 2.3×10−4 cm²/Vs was used for the 1-1 hole transport layer 511a, and a material having a refractive index of 1.85 and a hole mobility (μ2) of 1.1×10⁻² cm²/Vs was used for the 1-2 hole transport layer 511b. A refractive index difference between the 1-1 hole transport layer 511a and the 1-2 hole transport layer 511b is 0.04, and the hole mobility of the 1-2 hole transport layer 511b is faster.

In Experimental Example 4-1, the 1-1 hole transport layer 511a and the 1-2 hole transport layer 511b were manufactured with a thickness ratio of 8:2, and in Experimental Example 4-2, the 1-1 hole transport layer 511a and the 1-2 hole transport layer 511b were manufactured with a thickness ratio of 6:4. It was found that the luminous efficiency in Experimental Example 4-1 was improved to 105%, and the luminous efficiency in Experimental Example 4-2 was improved to 107%.

In Experimental Example 5-1 and Experimental Example 5-2, a material having a refractive index of 1.79 and a hole mobility of 2.3×10⁻⁴ cm²/Vs was used for the 1-1 hole transport layer 511a, and a material having a refractive index of 1.89 and a hole mobility of 6.8×10⁻⁵ cm²/Vs was used for the 1-2 hole transport layer 511b. In this case, a refractive index difference between the 1-1 hole transport layer 511a and the 1-2 hole transport layer 511b is 0.10, and the hole mobility of the 1-1 hole transport layer 511a is faster.

In Experimental Example 5-1, the 1-1 hole transport layer 511a and the 1-2 hole transport layer 511b were manufactured with a thickness ratio of 8:2, and in Experimental Example 5-2, the 1-1 hole transport layer 511a and the 1-2 hole transport layer 511b were manufactured with a thickness ratio of 6:4. It was found that the luminous efficiency in Experimental Example 5-1 was improved to 103%, and the luminous efficiency in Experimental Example 5-2 was improved to 103%,

In Experimental Example 6-1 and Experimental Example 6-2, a hole transport material having a refractive index of 1.99 and a hole mobility of 5.2×10⁻⁴ cm²/Vs was used for the 1-1 hole transport layer 511a, and a hole transport material having a refractive index of 1.85 and a hole mobility of 1.1×10⁻² cm²/Vs was used for the 1-2 hole transport layer 511b. In this case, a refractive index difference between the 1-1 hole transport layer 511a and the 1-2 hole transport layer 511b is 0.14, and the hole mobility of the 1-2 hole transport layer 511b is faster.

In Experimental Example 6-1, the 1-1 hole transport layer 511a and the 1-2 hole transport layer 511b were manufactured with a thickness ratio of 8:2, and in Experimental Example 6-2, the 1-1 hole transport layer 511a and the 1-2 hole transport layer 511b were manufactured with a thickness ratio of 6:4. It was found that the luminous efficiency in Experimental Example 6-1 was improved to 101%, and the luminous efficiency in Experimental Example 6-2 was improved to 105%,

According to a result of the review, when comparing Experimental Examples 4-2, 5-2, and 6-2 in which the thickness ratios of the 1-1 hole transport layer 511a and the 1-2 hole transport layer 511b are the same, it can be seen that the operating voltage becomes lower in the case of Experimental Examples 4-2 and 6-2 in which a difference in hole mobility is large. Accordingly, it can be seen that the operating voltage can be lowered when hole transport layers are manufactured by increasing the difference in hole mobility.

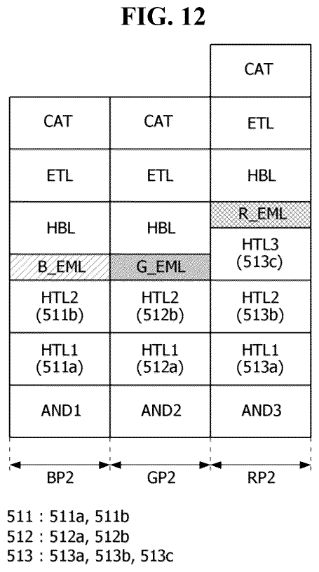

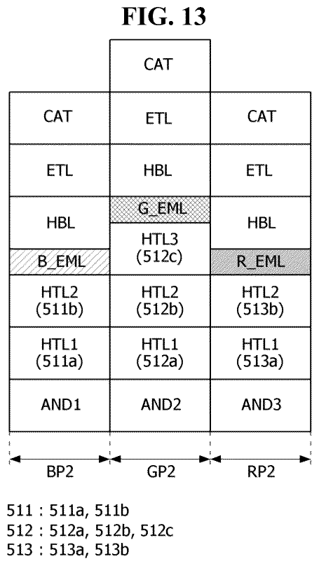

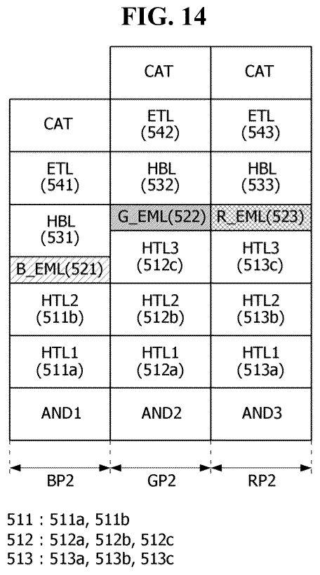

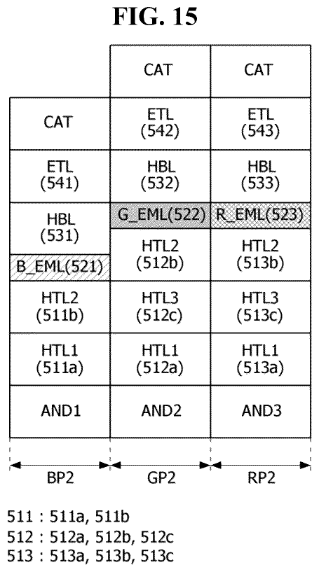

FIG. 12 is a view illustrating a second organic light-emitting element OLED2 according to a second embodiment of the present disclosure. FIG. 13 is a view illustrating a second organic light-emitting element OLED2 according to a third embodiment of the present disclosure. FIG. 14 is a view illustrating a second organic light-emitting element OLED2 according to a fourth embodiment of the present disclosure. FIG. 15 is a view illustrating a second organic light-emitting element OLED2 according to a fifth embodiment of the present disclosure.

Referring to FIGS. 12 to 15, in the second organic light-emitting element OLED2 according to the embodiments, a hole transport layer can be additionally disposed on at least one of a second sub light-emitting element GP2 and a third sub light-emitting element RP2. A configuration of each embodiment is described along with the following Table 5 and Table 6.

The following Table 5 is a table showing the results of measuring luminous efficiency after adjusting the refractive index (first refractive index) of a 2-1 hole transport layer 512a, the refractive index (second refractive index) of a 2-2 hole transport layer 512b, and the refractive index (third refractive index) of a 2-3 hole transport layer 512c differently in the second sub light-emitting element GP2. In Comparative Example 5, the output of a green light-emitting element having a single hole transport layer was measured.

The following Table 6 is a table showing the results of measuring luminous efficiency after adjusting the refractive index (first refractive index) of a 3-1 hole transport layer 513a, the refractive index (second refractive index) of a 3-2 hole transport layer 513b, and the refractive index (third refractive index) of a 3-3 hole transport layer 513c differently in the third sub light-emitting element RP2. In Comparative Example 6, the output of a red light-emitting element having a single hole transport layer was measured.

TABLE 5

| | First | Second | Third | |
|---|---|---|---|---|
| | refractive | refractive | refractive | Luminous |
| | index | index | index | efficiency |
| Comparative | 1.89 | — | — | 100% |
| Example 5 | | | | |
| Experimental | 1.89 | 2.05 | — | 103% |
| Example 7-1 | | | | |
| Experimental | 1.89 | 2.05 | 1.90 | 105% |
| Example 7-2 | | | | |
| Experimental | 1.89 | 1.98 | 2.02 | 107% |
| Example 7-3 | | | | |

TABLE 6

| | First | Second | Third | |
|---|---|---|---|---|
| | refractive | refractive | refractive | Luminous |
| | index | index | index | efficiency |
| Comparative | 1.89 | — | — | 100% |
| Example 6 | | | | |
| Experimental | 1.89 | 2.05 | — | 102% |
| Example 8-1 | | | | |
| Experimental | 1.89 | 2.05 | 1.92 | 106% |
| Example 8-2 | | | | |
| Experimental | 1.89 | 1.97 | 1.99 | 108% |
| Example 8-3 | | | | |

Referring to Table 5 above, in the case of Experimental Example 7-1, it can be seen that luminous efficiency is improved by stacking a plurality of hole transport layers, compared to Comparative Example 5. In the case of Experimental Example 7-2, the refractive indices of the 2-1 hole transport layer to the 2-3 hole transport layer 512a, 512b, and 512c change in the order of low->high->middle, and the luminous efficiency increased to 105%.

Further, in the case of Experimental Example 7-3, the refractive indices of the 2-1 hole transport layer to the 2-3 hole transport layer 512a, 512b, and 512c change in the order of low->middle->high, and the luminous efficiency increased to 107%.

Referring to Table 6 above, in the case of Experimental Example 8-1, it can be seen that luminous efficiency is improved by stacking a plurality of hole transport layers, compared to Comparative Example 6. In the case of Experimental Example 8-2, the refractive indices of the 3-1 hole transport layer to the 3-3 hole transport layer 513a, 513b, and 513c change in the order of low->high->middle, and the luminous efficiency increased to 106%. Further, in the case of Experimental Example 8-3, the refractive indices of the 3-1 hole transport layer to the 3-3 hole transport layer 513a, 513b, and 513c change in the order of low->middle->high, and the luminous efficiency increased to 108%.

Referring to FIG. 12, the third sub light-emitting element RP2 can further include the 3-3 hole transport layer 513c disposed on the 3-2 hole transport layer 513b.

The refractive index of the 3-3 hole transport layer 513c can be greater than the refractive index of the 3-1 hole transport layer 513a and smaller than the refractive index of the 3-2 hole transport layer 513b. For example, the refractive index of the 3-1 hole transport layer 513a can be 1.89, the refractive index of the 3-2 hole transport layer 513b can be 2.05, and the refractive index of the 3-3 hole transport layer 513c can be 1.90. However, the present disclosure is not necessarily limited thereto, and the refractive index of each hole transport layer can be changed within a range in which a magnitude relationship is maintained.

Referring to Experimental Example 8-2 in Table 6, it can be seen that the refractive indices of the 3-1 hole transport layer to the 3-3 hole transport layer 513a, 513b, and 513c change in the order of low->high->middle, and the luminous efficiency of red light increased to 106%.

Referring to FIG. 13, the second sub light-emitting element GP2 can further include the 2-3 hole transport layer 512c disposed on the 2-2 hole transport layer 512b.

The refractive index of the 2-3 hole transport layer 512c can be greater than the refractive index of the 2-1 hole transport layer 512a and smaller than the refractive index of the 2-2 hole transport layer 512b. For example, the refractive index of the 2-1 hole transport layer 512a can be 1.89, the refractive index of the 2-2 hole transport layer 512b can be 2.05, and the refractive index of the 2-3 hole transport layer 512c can be 1.98. However, the present disclosure is not necessarily limited thereto, and the refractive index of each hole transport layer can be changed within a range in which a magnitude relationship is maintained.

Referring to Experimental Example 7-2 in Table 5, it can be seen that the refractive indices change in the order of low->high->middle, and the luminous efficiency of green light increased to 105%.

Referring to FIG. 14, the second organic light-emitting element OLED2 can include the 2-3 hole transport layer 512c disposed on the 2-2 hole transport layer 512b in the second sub light-emitting element GP2 and the 3-3 hole transport layer 513c disposed on the 3-2 hole transport layer 513b in the third sub light-emitting element RP2.

Referring to Experimental Example 7-2 in Table 5, the luminous efficiency of green light increased to 105%, and referring to Experimental Example 8-2 in Table 6, it can be seen that the luminous efficiency of red light increased to 106%. Accordingly, the luminous efficiency of white light can also be improved as the luminous efficiency of each of the blue light, green light, and red light is improved.

Referring to FIG. 15, in the second organic light-emitting element OLED2 according to the fifth embodiment, the 2-3 hole transport layer 512c can be disposed between the 2-1 hole transport layer 512a and the 2-2 hole transport layer 512b in the second sub light-emitting element GP2 and the 3-3 hole transport layer 513c can be disposed between the 3-1 hole transport layer 513a and the 3-2 hole transport layer 513b in the third sub light-emitting element RP2.

In this case, the refractive index of the 2-3 hole transport layer 512c can be greater than the refractive index of the 2-1 hole transport layer 512a and smaller than the refractive index of the 2-2 hole transport layer 512b. The refractive index of the 3-3 hole transport layer 513c can be greater than the refractive index of the 3-1 hole transport layer 513a and smaller than the refractive index of the 3-2 hole transport layer 513b.

Referring to Experimental Example 7-3 in Table 5, the luminous efficiency of green light increased to 107%, and referring to Experimental Example 8-3 in Table 6, it can be seen that the luminous efficiency of red light increased to 108%. Accordingly, the luminous efficiency of white light can also be improved as the luminous efficiency of each of the blue light, green light, and red light is improved.

Although examples where two hole transport layers are set in the first sub light-emitting element BP2, two or three hole transport layers are set in the second sub light-emitting element GP2 and two or three hole transport layers are set in the third sub light-emitting element RP2 are described in the above, the present application is not limited thereto, and the number of hole transport layers in each sub light-emitting element is not limited thereto.

According to an aspect of the present disclosure, a display device can include a first sub light-emitting element including a first hole transport layer and a first organic light-emitting layer disposed on the first hole transport layer, the first hole transport layer including multiple sub-layers and refractive indexes of the multiple sub-layers decreasing in a direction toward the first organic light-emitting layer; a second sub light-emitting element including a second hole transport layer and a second organic light-emitting layer disposed on the second hole transport layer, the second hole transport layer including multiple sub-layers, wherein a refractive index of a sub-layer most distant away from the second organic light-emitting layer among the multiple sub-layers is the lowest; and a third sub light-emitting element including a third hole transport layer and a third organic light-emitting layer disposed on the third hole transport layer, the third hole transport layer including multiple sub-layers, wherein a refractive index of a sub-layer most distant away from the third organic light-emitting layer among the multiple sub-layers is the lowest.

For example, the first hole transport layer can include two sub-layers, the second hole transport layer can include two or three sub-layers, and the third hole transport layer can include two or three sub-layers.

For example, the second hole transport layer includes three sub-layers, wherein the refractive indexes of the three sub-layers increase in sequence in a direction toward the second organic light-emitting layer, or a sub-layer located at a middle position among the three sub-layers has the largest refractive index; and/or the third hole transport layer includes three sub-layers, wherein the refractive indexes of the three sub-layers increase in sequence in a direction toward the third organic light-emitting layer, or a sub-layer located at a middle position among the three sub-layers has the largest refractive index.

In addition, in one or more of the first hole transport layer to the third hole transport layer, hole mobility of respective sub-layers are different, so as to reduce the operating voltage.

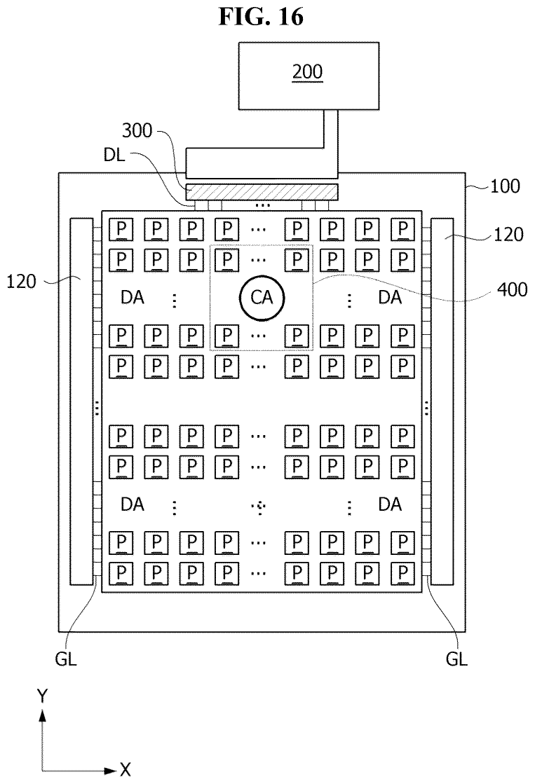

FIG. 16 is a view illustrating the display device according to one embodiment of the present disclosure.

Referring to FIG. 16, the display device can include a display panel 100 on which a pixel array is disposed on a screen, a display panel driver, and the like.

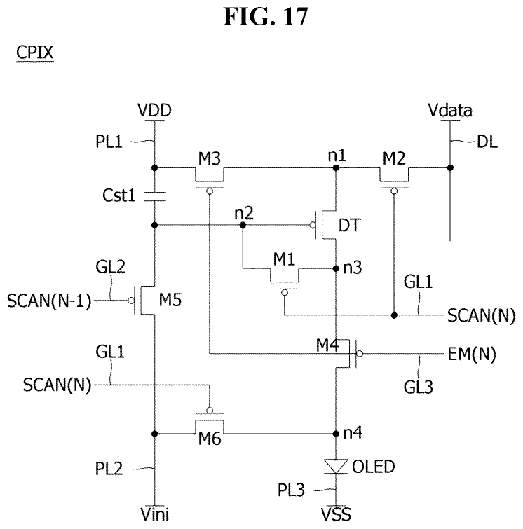

The pixel array of the display panel 100 can include data lines DL, gate lines GL intersecting the data lines DL, and pixels P connected to the data lines DL and the gate lines GL and arranged in a matrix form. The pixel array can further include power lines such as a VDD line PL1, a Vini line PL2, and a VSS line PL3 shown in FIG. 17.

The pixel array can be divided into the circuit layer 12 and the light-emitting element layer 14 as shown in FIG. 2. Further, a touch sensor array can be disposed on the light-emitting element layer 14. Here, as described above, each of the pixels of the pixel array can include two to four sub-pixels. Each of the sub-pixels can include a pixel circuit disposed in the circuit layer 12.

The screen of the display panel 100 on which an input image is reproduced can include a display region DA and an imaging region CA.

Each of the sub-pixels of the display region DA and the imaging region CA can include a pixel circuit. The pixel circuit can include a driving element which supplies current to a light-emitting element OLED, a plurality of switch elements which sample a threshold voltage of the driving element and switch a current path of the pixel circuit, a capacitor which maintains a gate voltage of the driving element, and the like. In this case, the pixel circuit can be disposed under the light-emitting element.

The imaging region CA can include a light transmission region TA disposed between the pixels and a camera module 400 disposed under the imaging region CA. The camera module 400 can photoelectrically convert light incident through the imaging region CA in an imaging mode using an image sensor, and can output captured image data by converting pixel data of an image output from the image sensor to digital data.

The display panel driver can write the pixel data of the input image to the pixels P. The pixels P can be interpreted as pixels including a plurality of sub-pixels.

The display panel driver can include a data driver which supplies a data voltage of pixel data to the data lines DL and a gate driver 120 which sequentially supplies gate pulses to the gate lines GL. Further, the data driver can be integrated into a drive integrated circuit (IC) 300. In addition, the display panel driver can further include a touch sensor driver omitted in the drawings.

The drive IC 300 can be attached to the display panel 100. The drive IC 300 receives the pixel data of the input image and a timing signal from a host system 200, supplies a data voltage of the pixel data to the pixels, and synchronizes the data driver and the gate driver 120.

The drive IC 300 can be connected to the data lines DL through data output channels and supply the data voltage of the pixel data to the data lines DL. The drive IC 300 can output a gate timing signal for controlling the gate driver 120 through gate timing signal output channels.

The gate driver 120 can include a shift register formed on the circuit layer of the display panel 100 together with the pixel array. The shift register of the gate driver 120 can sequentially supply gate signals to the gate lines GL under the control of a timing controller.

The gate signals can include a scan pulse and an EM pulse of an emission signal.

The host system 200 can be implemented as an application processor (AP). The host system 200 can transmit the pixel data of the input image to the drive IC 300 through a mobile industry processor interface (MIPI). The host system 200 can be connected to the drive IC 300 through, for example, a flexible printed circuit (FPC).

Meanwhile, the display panel 100 can be implemented as a flexible panel applicable to a flexible display.

The flexible panel can be manufactured as a so-called “plastic OLED panel.” The plastic OLED panel can include a back plate and a pixel array on an organic thin film adhered to the back plate. A touch sensor array can be formed on the pixel array.

The back plate can be a polyethylene terephthalate (PET) substrate. The pixel array and touch sensor array can be formed on the organic thin film. The back plate can block moisture permeation toward the organic thin film so that the pixel array can not be exposed to humidity.

The organic thin film can be a polyimide (PI) substrate. A multi-layer buffer film can be formed on the organic thin film with an insulating material. Further, the circuit layer 12 and the light-emitting element layer 14 can be stacked on the organic thin film.

In the display device of the present disclosure, the pixel circuit, the gate driver, and the like disposed in the circuit layer 12 can include a plurality of transistors. The transistors can be implemented as an oxide thin film transistor (TFT) including an oxide semiconductor, a low temperature poly silicon (LTPS) TFT including LTPS, and the like. Further, each of the transistors can be implemented as a p-channel TFT or an n-channel TFT.

A transistor is a three-electrode element including a gate, a source, and a drain. The source is an electrode which supplies carriers to the transistor. The carriers can start flowing from the source in the transistor. The drain is an electrode through which the carriers exit to the outside from the transistor.

The carriers in the transistor flow from the source to the drain. In the case of an n-channel transistor, since the carriers are electrons, a source voltage is lower than a drain voltage so that the electrons can flow from the source to the drain. The current in the n-channel transistor flows in a direction from the drain to the source.

In the case of a p-channel transistor (PMOS, p-channel metal-oxide semiconductor transistor), since carriers are holes, a source voltage is greater than a drain voltage so that holes can flow from the source to the drain. In the p-channel transistor, because holes flow from the source to the drain, current flows from the source to the drain. It should be noted that the source and the drain of a transistor are not fixed. For example, the source and the drain can be changed according to a voltage to be applied. Accordingly, the present disclosure is not limited by the source and the drain of the transistor. In the following description, the source and the drain of the transistor will be referred to as first and second electrodes.

The gate pulses can swing between a gate-on voltage and a gate-off voltage. The gate-on voltage can be set to a voltage greater than the threshold voltage of the transistor, and the gate-off voltage can be set to a voltage lower than the threshold voltage of the transistor.

The transistor can be turned on in response to the gate-on voltage and turned off in response to the gate-off voltage. In the case of an n-channel transistor, the gate-on voltage can be a gate-high voltage VGH, and the gate-off voltage can be a gate-low voltage VGL. In the case of a p-channel transistor, the gate-on voltage can be the gate-low voltage VGL and the gate-off voltage can be the gate-high voltage VGH.

A driving element of the pixel circuit can be implemented as a transistor. The electrical characteristics of the driving element should be uniform between all pixels, but there can be a difference between the pixels due to deviations in process and deviations in element characteristics, and the difference can change over the display driving time.

In order to compensate for deviations in electrical characteristics of the driving element, the display device can include an internal compensation circuit and an external compensation circuit. The internal compensation circuit can be added to the pixel circuit in each of the sub-pixels to sample a threshold voltage Vth and/or mobility of the driving element which changes according to the electrical characteristics of the driving element, and compensate for a change in real time.

The external compensation circuit can transmit the threshold voltage and/or the mobility of the driving element sensed through sensing lines respectively connected to the sub-pixels to an external compensation unit. The compensation unit of the external compensation circuit can compensate for a change in electrical characteristics of the driving element by reflecting a sensing result to modulate the pixel data of the input image.

Deviations in electrical characteristics of the driving element between the pixels can be compensated for by sensing a voltage of the pixel which changes according to the electrical characteristics of an external compensation driving element and modulating the data of the input image in an external circuit based on the sensed voltage.

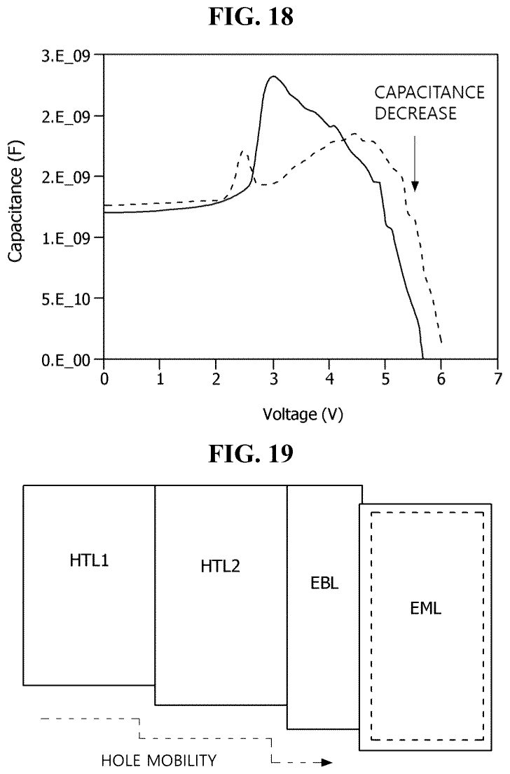

FIG. 17 is a view illustrating an example of the pixel circuit. FIG. 18 is a view illustrating a change in capacitance of the organic light-emitting element according to a change in voltage. FIG. 19 is a view illustrating an energy level of the organic light-emitting element.

The pixel circuit shown in FIG. 17 can be equally applied to pixel circuits of the first display region DA and the second display region CA.

Referring to FIG. 17, the pixel circuit CPIX can include a light-emitting element OLED, a driving element DT supplying current to the light-emitting element OLED, and an internal compensation circuit which samples a threshold voltage Vth of the driving element DT using a plurality of switch elements M1 to M6 and compensates for a gate voltage of the driving element DT by the threshold voltage Vth of the driving element DT. Each of the driving element DT and the switch elements M1 to M6 can be implemented as a p-channel TFT.

The light-emitting element OLED can include an organic compound layer formed between an anode and a cathode. The organic compound layer can include a hole injection layer HIL, a hole transport layer HTL, a light-emitting layer EML, an electron transport layer ETL, and an electron injection layer EIL, but is not limited to. When the voltage is applied to the anode and the cathode of the OLED, since holes, which passed through the hole transport layer HTL, and electrons, which passed through the electron transport layer ETL, move to the light-emitting layer EML and thus excitons are formed, visible light can be emitted from the light-emitting layer EML.

According to the embodiment, in a second organic light-emitting element, since a difference in hole mobility between a lower hole transport layer and an upper hole transport layer of the hole transport layers can be set to be large, parasitic capacitance and an operating voltage can be lowered.

Referring to FIGS. 18 and 19, the refractive index is proportional to the square root of a dielectric constant. Further, the capacitance is proportional to the dielectric constant. For example, the dielectric constant and capacitance increase as the refractive index increases, and the dielectric constant and capacitance decrease as the refractive index decreases. Accordingly, the capacitance can be adjusted according to the refractive indices of the hole transport layers constituting the light-emitting element.

According to the embodiment, in the case of a blue light-emitting element, since the hole transport layers are relatively low refractive index layers, capacitance can be reduced. Further, a green region and a red region have relatively high refractive indices, but capacitance can be reduced by increasing hole mobility.

Accordingly, the parasitic capacitance of the second organic light-emitting element OLED2 can be smaller than the parasitic capacitance of the first organic light-emitting element OLED1. Further, the hole mobility of the hole transport layers of the second organic light-emitting element OLED2 can be higher than the hole mobility of hole transport layers of the first organic light-emitting element OLED1.

For example, the parasitic capacitance of a first sub light-emitting element to a third sub light-emitting element constituting the second organic light-emitting element OLED2 can be smaller than the parasitic capacitance of a first sub light-emitting element to a third sub light-emitting element constituting the first organic light-emitting element OLED1.

Referring to FIG. 17 again, the anode of the light-emitting element OLED can be connected to a fourth node n4 between fourth and sixth switch elements M4 and M6. The fourth node n4 can be connected to the anode of the light-emitting element OLED, a second electrode of the fourth switch element M4, and a second electrode of the sixth switch element M6. The cathode of the light-emitting element OLED can be connected to the VSS line PL3 to which a low-potential power supply voltage VSS is applied. The light-emitting element OLED can emit light with a current Ids flowing according to a gate-source voltage Vgs of the driving element DT. A current path of the light-emitting element OLED can be switched by the third and fourth switch elements M3 and M4.

A storage capacitor Cstl can be connected between the VDD line PL1 and a second node n2. A data voltage Vdata compensated by the threshold voltage Vth of the driving element DT can be charged in the storage capacitor Cstl. Since the data voltage Vdata in each of the sub-pixels is compensated by the threshold voltage Vth of the driving element DT, the deviation in characteristics of the driving element DT in the sub-pixels can be compensated for.

A first switch element M1 can be turned on in response to a gate-on voltage VGL of an Nth scan pulse SCAN(N) to connect a second node n2 and a third node n3. Here, N can be a real number such as a positive integer. The second node n2 can be connected to a gate electrode of the driving element DT, a first electrode of the storage capacitor Cstl, and a first electrode of the first switch element M1. The third node n3 can be connected to a second electrode of the driving element DT, a second electrode of the first switch element M1, and a first electrode of the fourth switch element M4. A gate electrode of the first switch element M1 is connected to a first gate line GL1 to receive the Nth scan pulse SCAN(N). The first electrode of the first switch element M1 can be connected to the second node n2, and the second electrode of the first switch element M1 can be connected to the third node n3.

Since the first switch element M1 is turned on only in one very short horizontal period 1H in which the Nth scan signal SCAN(N) is generated as the gate-on voltage VGL in one frame period, and thus maintains an off state for approximately one frame period, leakage current can be generated in the off state of the first switch element ML.

A second switch element M2 can be turned on in response to the gate-on voltage VGL of the Nth scan pulse SCAN(N) to supply the data voltage Vdata to the first node n1. A gate electrode of the second switch element M2 is connected to the first gate line GL1 to receive the Nth scan pulse SCAN(N). A first electrode of the second switch element M2 can be connected to the first node n1. A second electrode of the second switch element M2 can be connected to the data line DL to which the data voltage Vdata is applied. The first node n1 can be connected to the first electrode of the second switch element M2, a second electrode of the third switch element M3, and the first electrode of the driving element DT.

The third switch element M3 can be turned on in response to the gate-on voltage VGL of an emission signal EM(N) to connect the VDD line PL1 to the first node n1. A gate electrode of the third switch element M3 is connected to a third gate line GL3 to receive the emission signal EM(N). A first electrode of the third switch element M3 can be connected to the VDD line PL1. The second electrode of the third switch element M3 can be connected to the first node n1.

The fourth switch element M4 can be turned on in response to the gate-on voltage VGL of the emission signal EM(N) to connect the third node n3 to the anode of the light-emitting element OLED. A gate electrode of the fourth switch element M4 is connected to the third gate line GL3 to receive the emission signal EM(N). The first electrode of the fourth switch element M4 can be connected to the third node n3, and the second electrode of the fourth switch element M4 can be connected to the fourth node n4.

The fifth switch element M5 can be turned on in response to a gate-on voltage VGL of an N-lth scan pulse SCAN(N-1) to connect the second node n2 to the Vini line PL2. A gate electrode of the fifth switch element M5 is connected to a second gate line GL2 to receive the N-lth scan pulse SCAN(N-1). A first electrode of the fifth switch element M5 can be connected to the second node n2, and a second electrode of the fifth switch element M5 can be connected to the Vini line PL2.

The sixth switch element M6 can be turned on in response to the gate-on voltage VGL of the Nth scan pulse SCAN(N) to connect the Vini line PL2 to the fourth node n4. A gate electrode of the sixth switch element M6 is connected to the first gate line GL1 to receive the Nth scan pulse SCAN(N). A first electrode of the sixth switch element M6 can be connected to the Vini line PL2, and the second electrode of the sixth switch element M6 can be connected to the fourth node n4.

The driving element DT can drive the light-emitting element OLED by adjusting the current Ids flowing through the light-emitting element OLED according to the gate-source voltage Vgs. The driving element DT can include the gate electrode connected to the second node n2, the first electrode connected to the first node n1, and the second electrode connected to the third node n3.

According to an embodiment of the present disclosure, the luminance of a light-emitting element disposed in an imaging region can be improved. Accordingly, low-power driving can be possible.

Further, since the luminance of the light-emitting element disposed in the imaging region is improved, luminance uniformity between a display region and the imaging region can be improved.

In addition, the uniformity of white light emitted from the light-emitting element disposed in the imaging region can be improved.

Effects of the present disclosure are not limited to the above-mentioned effects, and other effects which are not mentioned will be clearly understood by those skilled in the art from the disclosure of the claims.

Although the embodiments of the present disclosure have been described in more detail with reference to the accompanying drawings, the present disclosure is not necessarily limited to these embodiments, and various modifications can be made herein without departing from the scope of the technical spirit of the present disclosure. Accordingly, the embodiments disclosed in the present disclosure are not intended to limit but to describe the technical spirit of the present disclosure, and the scope of the technical spirit of the present disclosure is not limited by these embodiments. Thus, it should be understood that the embodiments described above are exemplary in all aspects and not limited. The scope of the present disclosure should be understood by the claims, and it should be understood that all technical ideas within the same scope are included in the scope of the present disclosure.

What is claimed is:

1. A display device comprising:
a first sub light-emitting element including a 1-1 hole transport layer, a 1-2 hole transport layer disposed on the 1-1 hole transport layer, and a first organic light-emitting layer disposed on the 1-2 hole transport layer;
a second sub light-emitting element including a 2-1 hole transport layer, a 2-2 hole transport layer disposed on the 2-1 hole transport layer, and a second organic light-emitting layer disposed on the 2-2 hole transport layer; and
a third sub light-emitting element including a 3-1 hole transport layer, a 3-2 hole transport layer disposed on the 3-1 hole transport layer, and a third organic light-emitting layer disposed on the 3-2 hole transport layer,
wherein a refractive index of the 1-1 hole transport layer is greater than a refractive index of the 1-2 hole transport layer, and
a refractive index of the 2-1 hole transport layer is less than a refractive index of the 2-2 hole transport layer.

2. The display device of claim 1, wherein:
the refractive index of the 1-1 hole transport layer is greater than the refractive index of the 2-1 hole transport layer; and
the refractive index of the 1-2 hole transport layer is less than the refractive index of the 2-2 hole transport layer.

3. The display device of claim 1, wherein a refractive index of the 3-1 hole transport layer is less than a refractive index of the 3-2 hole transport layer.

4. The display device of claim 1, wherein:
the first organic light-emitting layer is configured to emit light in a blue wavelength range, the second organic light-emitting layer is configured to emit light in a green wavelength range, and
the third organic light-emitting layer is configured to emit light in a red wavelength range.

5. The display device of claim 1, wherein a thickness of the 1-2 hole transport layer is greater than a thickness of the 1-1 hole transport layer.

6. The display device of claim 5, wherein a thickness of the 2-2 hole transport layer is greater than a thickness of the 2-1 hole transport layer.

7. The display device of claim 1, wherein:
the refractive index of the 1-1 hole transport layer is greater than a refractive index of the 3-1 hole transport layer; and
the refractive index of the 1-2 hole transport layer is less than a refractive index of the 3-2 hole transport layer.

8. The display device of claim 1, wherein the refractive indices of the 1-1 hole transport layer, the 2-2 hole transport layer, and the 3-2 hole transport layer are the same.

9. The display device of claim 8, wherein the refractive indices of the 1-2 hole transport layer, the 2-1 hole transport layer, and the 3-1 hole transport layer are the same.

10. The display device of claim 1, wherein:
the second sub light-emitting element further includes a 2-3 hole transport layer disposed between the 2-1 hole transport layer and the 2-2 hole transport layer,
the third sub light-emitting element further includes a 3-3 hole transport layer disposed between the 3-1 hole transport layer and the 3-2 hole transport layer,
a refractive index of the 2-3 hole transport layer is greater than the refractive index of the 2-1 hole transport layer and is less than the refractive index of the 2-2 hole transport layer, and
a refractive index of the 3-3 hole transport layer is greater than a refractive index of the 3-1 hole transport layer and is less than a refractive index of the 3-2 hole transport layer.

11. The display device of claim 1, further comprising:
a 2-3 hole transport layer disposed on the 2-2 hole transport layer; and
a 3-3 hole transport layer disposed on the 3-2 hole transport layer,
wherein a refractive index of the 2-3 hole transport layer is greater than the refractive index of the 2-1 hole transport layer and is less than the refractive index of the 2-2 hole transport layer, and
a refractive index of the 3-3 hole transport layer is greater than a refractive index of the 3-1 hole transport layer and is less than a refractive index of the 3-2 hole transport layer.

12. The display device of claim 1, wherein a hole mobility of the 1-1 hole transport layer is lower than a hole mobility of the 1-2 hole transport layer.

13. A display device comprising:
a first display region where a plurality of first pixels are disposed; and
a second display region including a pixel region where a plurality of second pixels are disposed, and a plurality of light transmission regions disposed between the plurality of second pixels,
wherein a number of the plurality of second pixels per unit area is less than a number of the plurality of first pixels per unit area,
the plurality of first pixels include a first organic light-emitting element,
the plurality of second pixels include a second organic light-emitting element, and
a refractive index of a hole transport layer of the first organic light-emitting element is different from a refractive index of at least one hole transport layer of the second organic light-emitting element.

14. The display device of claim 13, wherein:
the hole transport layer of the first organic light-emitting element has a constant refractive index in a thickness direction; and
the hole transport layer of the second organic light-emitting element has a section in which a refractive index changes in the thickness direction.

15. The display device of claim 13, wherein the second organic light-emitting element includes:
a first sub light-emitting element including a 1-1 hole transport layer, a 1-2 hole transport layer disposed on the 1-1 hole transport layer, and a first organic light-emitting layer disposed on the 1-2 hole transport layer;
a second sub light-emitting element including a 2-1 hole transport layer, a 2-2 hole transport layer disposed on the 2-1 hole transport layer, and a second organic light-emitting layer disposed on the 2-2 hole transport layer; and
a third sub light-emitting element including a 3-1 hole transport layer, a 3-2 hole transport layer disposed on the 3-1 hole transport layer, and a third organic light-emitting layer disposed on the 3-2 hole transport layer,
wherein a refractive index of the 1-1 hole transport layer is greater than a refractive index of the 1-2 hole transport layer, and
a refractive index of the 2-1 hole transport layer is less than a refractive index of the 2-2 hole transport layer.

16. The display device of claim 15, wherein:
the refractive index of the 1-1 hole transport layer is greater than the refractive index of the 2-1 hole transport layer; and
the refractive index of the 1-2 hole transport layer is less than the refractive index of the 2-2 hole transport layer.

17. The display device of claim 15, wherein a refractive index of the 3-1 hole transport layer is less than a refractive index of the 3-2 hole transport layer.

18. The display device of claim 15, wherein a thickness of the 1-2 hole transport layer is greater than a thickness of the 1-1 hole transport layer, and
wherein a thickness of the 2-2 hole transport layer is greater than a thickness of the 2-1 hole transport layer.

19. A display device comprising:
a first display region including a plurality of first pixels disposed therein;
a second display region including a pixel region where a plurality of second pixels are disposed, and a plurality of light transmission regions disposed between the plurality of second pixels; and
an optical sensor disposed to overlap the second display region,
wherein the plurality of first pixels include a first organic light-emitting element,
the plurality of second pixels include a second organic light-emitting element,
a refractive index of a hole transport layer of the first organic light-emitting element is different from a refractive index of a hole transport layer of the second organic light-emitting element, and
a parasitic capacitance of the second organic light-emitting element is less than a parasitic capacitance of the first organic light-emitting element.

20. The display device of claim 19, wherein the hole transport layer of the second organic light-emitting element has a hole mobility greater than a hole mobility of the hole transport layer of the first organic light-emitting element.
